(19) United States
(12) Patent Application Publication
(10) Pub. No.: US 2018/0192525 A1
(43) Pub. Date: Jul. 5, 2018

(54) DISPLAY MODULE AND METHOD FOR PRODUCING THE SAME

(71) Applicant: HEYI INTELLIGENT TECHNOLOGY (SHENZHEN) CO., LTD, Beijing (CN)

(72) Inventors: Yajun Yun, Beijing (CN); Qian CAO, Beijing (CN); Wenhua SU, Beijing (CN); Jian YAO, Beijing (CN); Baiyu PAN, Beijing (CN); Ji WANG, Beijing (CN)

(21) Appl. No.: 15/738,383

(22) PCT Filed: Sep. 13, 2016
(86) PCT No.: PCT/CN2016/098805

§ 371 Date: Dec. 20, 2017

(30) Foreign Application Priority Data
Nov. 19, 2015 (CN) 201510802211.1

(51) Int. Cl. H05K 5/00; F21V 8/00; H05K 5/02; H05K 5/03

(52) U.S. Cl. CPC H05K 5/0017; G02B 6/0055; G02B 6/0065; H05K 5/03; G02B 6/0088; H05K 5/0247; G02B 6/0083

(57) ABSTRACT

The present disclosure relates to a display module and a method for producing the same. The method comprises: providing a reflective sheet inside an accommodating cavity of a rear cover of the display module, the accommodating cavity being formed by a bottom plate and a side plate of the rear cover; providing a backlight source above the reflective sheet, and fixing the backlight source to an inner surface of the side plate; providing a light guide plate above the reflective sheet and on a side of the backlight source, and connecting the light guide plate to the side plate; providing an optical film above the light guide plate, and connecting the optical film to the side plate; and providing a display panel above the optical film, and fixing the display panel to the side plate. By the present disclosure, the backboard, the plastic central frame and the front frame of the display module such as a television can be replaced with a rear cover. Each layer of the display module can be assembled via the rear cover, without the need for the front frame and the central frame, which helps to lighten the weight of the display module, shorten the supply chain and save the cost for the materials.

### CROSS-REFERENCE TO RELATED APPLICATION

This application is the national stage under 35 USC 371 of PCT application PCT/CN2016/098805 and claims the benefit of Chinese Patent Application No. 201510802211.1, filed on Nov. 19, 2015, the entire contents of which are incorporated herein by reference.

### TECHNICAL FIELD

The present disclosure relates to the field of display, and more particularly, to a display module and a method for producing the same.

### BACKGROUND

The structure of some backlight modules or display modules can be extremely complicated. As shown in FIG. 1, a backlight module may include a front frame, a display panel, optical means, a plastic central frame, a metal backboard, a cover for PCB (Printed Circuit Board), and so on. The optical means may include a LGP (Light Guide Plate) and a reflective sheet. Each of the components needs to be assembled manually, for example, the front frame and the backboard need to be screwed together.

Some backlight modules or display modules have various disadvantages. For example, it can be troublesome to maintain the supply chain, and to provide management and control for including a large number of components. The cost for manufacturing can be high if the module includes a large number of materials, and it may be time-consuming and may require high cost of labor and material as there may be a large quantity of materials and they may need to be assembled manually.

### SUMMARY

In one aspect, in general, the present disclosure describes techniques to reduce the quantity of materials of a display module, and to provide a display module that is convenient to assemble, and a method for producing the same.

In another aspect, in general, the present disclosure describes a method for producing a display module, comprising:

providing a reflective sheet inside an accommodating cavity of a rear cover of the display module, the accommodating cavity being formed by a bottom plate and a side plate of the rear cover;

providing a backlight source above the reflective sheet, and fixing the backlight source to an inner surface of the side plate;

providing a light guide plate above the reflective sheet and on a side of the backlight source, and connecting the light guide plate to the side plate;

providing an optical film above the light guide plate, and connecting the optical film to the side plate; and

providing a display panel above the optical film, and fixing the display panel to the side plate.

Aspects can include one or more of the following features.

With regard to the above method, in one possible implementation, providing the backlight source above the reflective sheet comprises:

providing the backlight source in a groove between the side plate and the bottom plate, wherein a protrusion protruding toward the inside of the accommodating cavity is provided on an inner surface of the side plate, and the groove is formed between the protrusion and the bottom plate.

With regard to the above method, in one possible implementation, the protrusion is provided on inner surfaces, facing each other, of the rear cover.

With regard to the above method, in one possible implementation, connecting the light guide plate to the side plate comprises:

engaging at least one side of the light guide plate with the groove.

With regard to the above method, in one possible implementation, connecting the optical film to the side plate comprises:

hitching the optical film to a film hanger located on the protrusion in such manner that a lower surface of the optical film is in contact with an upper surface of the light guide plate.

With regard to the above method, in one possible implementation, fixing the display panel to the side plate comprises:

adhering the display panel to the inner surface of the side plate and an upper surface of the protrusion.

In another aspect, in general, the present disclosure further describes a display module, comprising:

a rear cover comprising an accommodating cavity, the accommodating cavity being formed by a bottom plate and a side plate of the rear cover;

a reflective sheet located on an upper surface of the rear cover;

a backlight source located above the reflective sheet and connected to the side plate;

a light guide plate located above the reflective sheet and the backlight source and connected to the side plate;

an optical film located above the light guide plate and connected to the side plate; and

a display panel located above the optical film and fixed to the side plate,

wherein, the reflective sheet, the backlight source, the light guide plate and the optical film are located within the accommodating cavity.

Aspects can include one or more of the following features.

Regarding the above display module, in one possible implementation, a protrusion protruding toward the inside of the accommodating cavity is provided on an inner surface of the side plate, a groove is formed between the protrusion and the bottom plate, and the backlight source and the light guide plate are provided within the groove.

Regarding the above display module, in one possible implementation, the protrusion is provided on inner surfaces of two side plates, facing each other, of the rear cover.

Regarding the above display module, in one possible implementation, a recess for housing an electrical connection terminal of the backlight source is provided on a part of the bottom plate that is adjacent to the groove.

Regarding the above display module, in one possible implementation, a plurality of film hangers are provided on the protrusion, and the optical film is hitched to the film hangers with a lower surface of the optical film in contact with an upper surface of the light guide plate.

Regarding the above display module, in one possible implementation, the display panel is adhered to the inner surface of the side plate and an upper surface of the protrusion.

Aspects may have one or more of the following advantages. The backboard, the plastic central frame and the front frame of the display module, such as a television, can be replaced with a rear cover. Each layer of the display module can be assembled via the rear cover, without the need for the front frame and the central frame. This dramatically reduces the components or the key materials for the display module, which helps to lighten the weight of the display module, reduces the supply chain and saves the cost for the materials. Several key materials are integrated in the rear cover, thereby further lowering the cost. The rear cover with a simplified design can help to save the working hours and labors and eliminate incompatibility between the materials, so that the precision of assembly and the yield of production can be greatly improved.

Additional features and aspects of the present disclosure will become apparent from the following description of exemplary embodiments with reference to the attached drawings.

### BRIEF DESCRIPTION OF THE DRAWINGS

The drawings, which are incorporated in and constitute part of the specification, together with the description, illustrate exemplary embodiments, features and aspects of the present disclosure and serve to explain the principles of the present disclosure.

FIG. 1 is a diagram showing the structure of a display module.

FIG. 2 is a flow chart showing a method for producing a display module according to an embodiment of the present disclosure.

FIGS. 3a and 3b are diagrams respectively showing enlarged structures of a part of a display module according to an embodiment of the present disclosure.

FIG. 4 is a diagram showing a display module provided with a light guide plate according to an embodiment of the present disclosure.

FIG. 5 is a diagram showing a display module provided with a backlight source according to an embodiment of the present disclosure.

FIG. 6 is a diagram showing a film hanger provided within a rear cover of the backlight module according to an embodiment of the present disclosure.

FIG. 7 is a diagram showing the layered structure of a display module according to an embodiment of the present disclosure.

FIG. 8 is a diagram showing the structure of a recess provided in a rear cover of the display module according to an embodiment of the present disclosure.

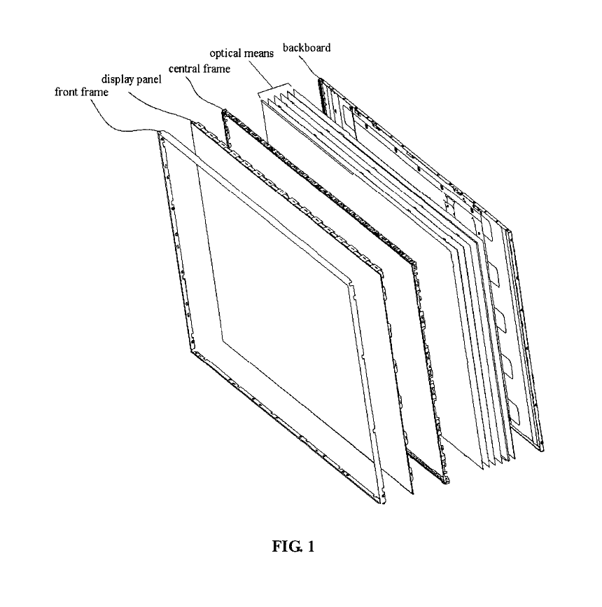

### REFERENCE SIGNS

1: rear cover

2: bottom plate

3: side plate

4: protrusion

5: groove

6: backlight source

8: recess

9: electrical connection terminal

10: film hanger

11: accommodating cavity

13: optical film

31: front surface of first step

32: side surface of first step

41: front surface of second step

42: side surface of second step

7: light guide plate

71: reflective sheet

### DETAILED DESCRIPTION

Various exemplary embodiments, features and aspects of the present disclosure will be described in detail with reference to the drawings. The same reference numerals in the drawings represent components having the same or similar functions. Although various aspects of the embodiments are shown in the drawings, it is unnecessary to proportionally draw the drawings unless otherwise specified.

Herein the term “exemplary” means “used as an instance or example, or explanatory”. An “exemplary” embodiment given here is not necessarily construed as being superior to or better than other examples.

Numerous details are given in the following embodiments for the purpose of better explaining the present disclosure. It should be understood by a person skilled in the art that the present disclosure can be realized even without some of those details. In some of the examples, methods, means, units and circuits that are well known to a person skilled in the art are not described in detail so that the principle of the present disclosure become apparent.

### Embodiment 1

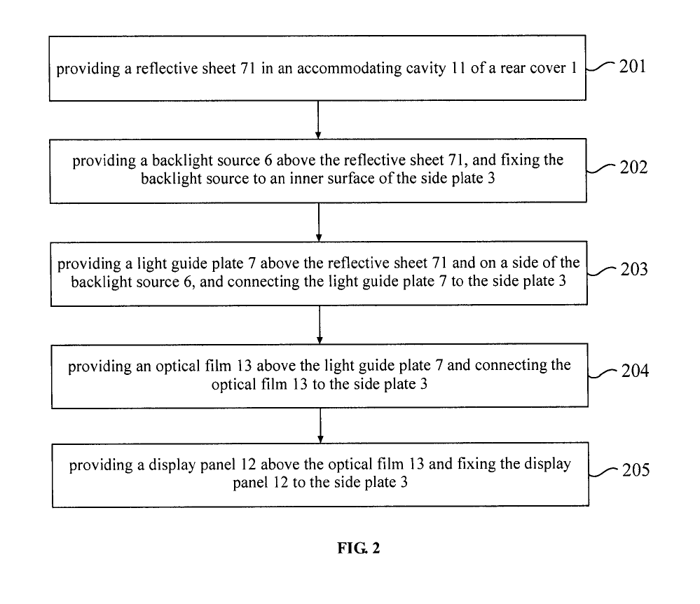

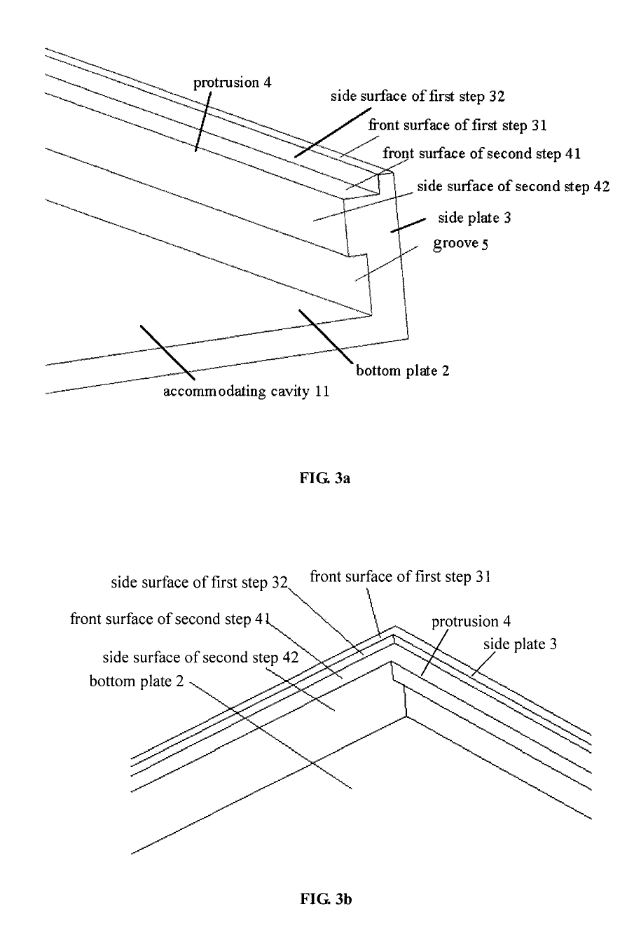

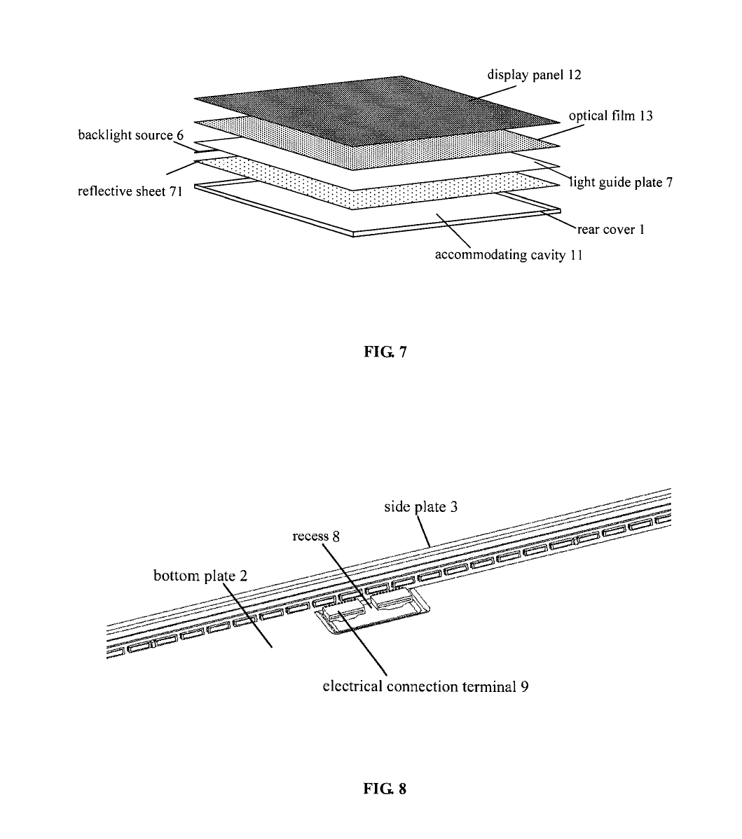

FIG. 2 is a flow chart showing a method for producing a display module according to an embodiment of the present disclosure. As shown in FIG. 2, and referring to FIGS. 3a to 9, the method for producing the display module may mainly include the following steps:

Step 201, providing a reflective sheet 71 in an accommodating cavity 11 of a rear cover 1, and as shown by FIGS. 3a-7, the rear cover I includes the accommodating cavity 11 formed by a bottom plate 2 and a side plate 3.

Specifically, a reflective sheet 71 may be attached to an upper surface of the bottom plate 2 and sized according to the size of the light emitting area. Preferably, the rear cover 1 may be formed by plastic materials. In this embodiment, the rear cover 1 may be formed by cast aluminum or cast magnesium to achieve high intensity and light weight. However, the material for the rear cover 1 of the present disclosure is not limited to the above materials, and it may include but is not limited to metal materials such as aluminum alloy, cast aluminum and cast magnesium, and high polymer materials such as plastic resin. In this embodiment, the components of the rear cover I may be produced by an integral forming process. The integral forming process, according to the different materials, may select from processing methods including but not limited to punching, press molding, integral casting, injection molding, and hot-pressing.

The rear cover 1 of the present disclosure, however, may be manufactured separately according to the designs. The components, including the bottom plate 2, the side plate 3, the protrusion 4 and so on, can be connected by methods including but not limited to bonding, welding, riveting, and joggling.

Step 202, providing a backlight source 6 above the reflective sheet 71, and fixing the backlight source to an inner surface of the side plate 3.

In one possible implementation, as shown in FIG. 5, the backlight source 6 is provided in a groove 5 between the side plate 3 and the bottom plate 2, a protrusion 4 protruding toward the inside of the accommodating cavity 11 is provided on the inner surface of a side plate 3, and the groove 5 is formed between the protrusion 4 and the bottom plate 2. Preferably, the protrusion 4 may be provided on the inner surfaces of two side plates facing each other such that when the light guide plate 7 is installed, the light guide plate 7 can be inserted into the groove 5 under the protrusion 4 because of the bendable property of the light guide plate 7, so as to be fixed. Alternatively, the protrusion may be provided on the inner surfaces of three or four of side plates. On this condition, one of the side plates 3 might be set to be demountable so as to facilitate the assembly.

In this embodiment, the backlight source 6 is preferably a light bar made of LEDs (Light Emitting Diode). It can be understood that the backlight source 6 includes but is not limited to a flat fluorescent lamp, a bulb, a light bar made of LEDs, a linear light source made of cold cathode fluorescent tubes, a strip shaped EL (electroluminescent), OELD (Organic Electroluminescent Diodes), and so on. Any illumination device that can be used as a backlight source of a backlight module is applicable in the present disclosure. The backlight source 6 of the present disclosure may also be various combinations of the abovementioned light sources.

Step 203, providing a light guide plate 7 above the reflective sheet 71 and on a side of the backlight source 6, and connecting the light guide plate 7 to the side plate 3.

In one possible implementation, referring to FIG. 5, at least one side of the light guide plate 7 is engaged with the groove 5.

In this embodiment, the rear cover 1 may have a rectangular shape and includes four side plates 3 and a bottom plate 2, and the groove 5 formed by one of the side plates 3 and the bottom plate 2 may be used to accommodate the backlight source 6. Referring to FIG. 5, the backlight source 6 and the light guide plate 7 may be located on the same side. Further, if the side accommodating the backlight source 6 is used as a light entering side, the light guide plate 7 may be fixed inside the groove 5 formed by the bottom plate 2 and the side plate 3 which is opposite to the light entering side. The groove 5 might have functions of pressing and storing the light guide plate 7. At least one side of the light guide plate 7 can be engaged with the groove 5 so as to prevent the light guide plate 7 from warping.

Though in this embodiment, the backlight source 6 is provided in the groove 5 formed by the bottom plate and one of the four side plates of the rear cover 1, it can be understood that the backlight source 6 can be provided in the groove 5 formed by the bottom plate and two, three or four of the side plates of the rear cover 1. According to the demand of application, the backlight source 6 may fill up the groove 5 formed by one side plate and the bottom plate of the rear cover 1 or the groove 5 formed by several side plates and the bottom plate of the rear cover 1, or fill up a part of the groove 5 formed by one or more side plates and the bottom plate of the rear cover 1.

Step 204, providing an optical film 13 above the light guide plate 7 and connecting the optical film 13 to the side plate 3.

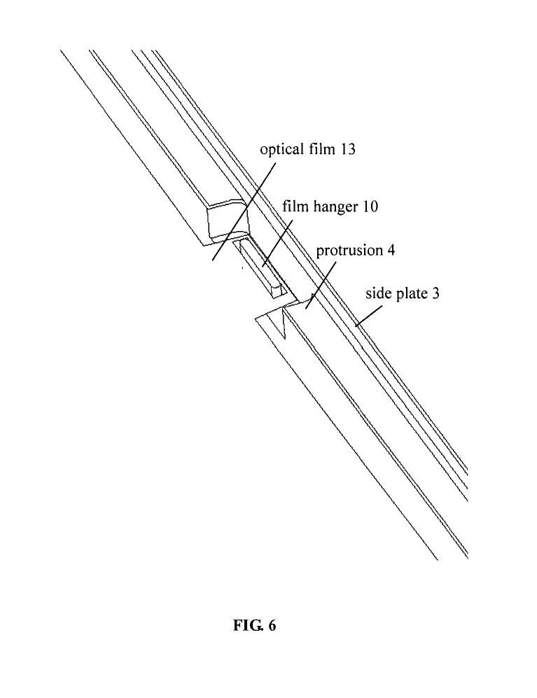

In one possible implementation, referring to FIG. 6, the optical film 13 may be hitched to a film hanger 10 on the protrusion such that a lower surface of the optical film 13 contacts an upper surface of the light guide plate 7.

As shown in FIG. 6, a plurality of film hangers 10 may be provided on the protrusion 4 for locating and fixing the optical film 13, such that the optical film 13 located above the light guide plate 7 can be hitched to the film hanger 10. For example, a recess may be formed on the protrusion 4, and the protruding film hanger 10 is provided in the recess. The depth of the recess may be determined according to the thickness of the optical film 13 and is preferably determined such that the optical film 13 happens to be attached to the upper surface of the light guide plate 7 when the optical film 13 is hitched to the film hanger 10. The structure of the film hanger 10 shown in FIG. 6 is merely an exemplary example, and the protruding film hanger 10 can also be provided on a side surface 42 of a second step of the protrusion 4, without a recess formed in the protrusion 4. Also, a connection between the optical film 13 and the protrusion 4 might be realized by other structures.

Step 205, providing a display panel 12 above the optical film 13 and fixing the display panel 12 to the side plate 3.

In one possible implementation, referring to FIGS. 3a to 5, the display panel 12 may be adhered to the inner surface of the side plate 3 and the upper surface of the protrusion 4. Specifically, an adhesive may be applied to coat the inner surface of the side plate 3 and the upper surface of the protrusion 4, a display panel may cover the optical film 13 and be attached to the inner surface of the side plate 3 and the upper surface of the protrusion by the adhesive, so that the display panel is fixed to the side plate 3 of the backlight module.

Preferably, in order to better support the display panel and prevent dust from entering, as shown in FIGS. 3a and 3b, the inner surface of the side plate 3 that is not provided with the protrusion 4 is constructed to have a step structure. The upper surface of the step structure is located in the same plane with the upper surface of the protrusion, thus the inner surface of the side plate 3, the upper surface of the step structure and the upper surface of the protrusion may be used to locate and limit the display panel 12. During the assembling process, an adhesive may be applied to coat the inner surface of the side plate 3, the upper surface of the step structure and the upper surface of the protrusion 4. The display panel covers the optical film 13 and is attached to the inner surface of the side plate 3, the upper surface of the step structure and the upper surface of the protrusion by the adhesive, so that the display panel is fixed to the side plate 3 of the backlight module.

In one possible implementation, the upper surface of the side plate 3 may be a curved surface so that a smooth transition from the edge of the display panel 12 to the side plate 3 can be realized.

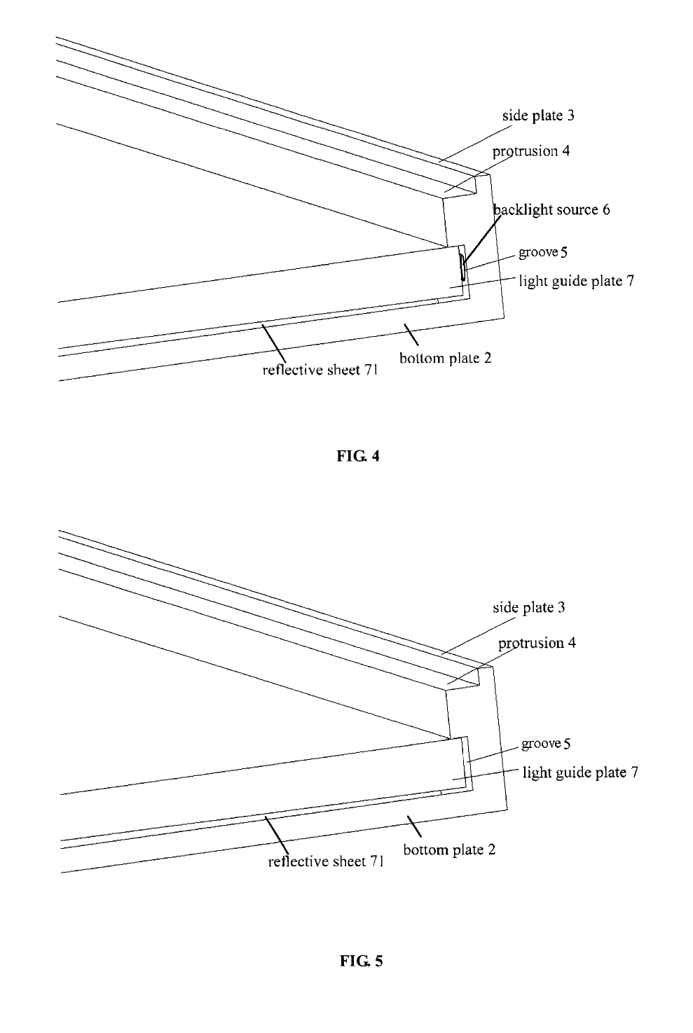

In one possible implementation, the upper surface of the side plate 3 may be a planar surface. Thus, as shown in FIGS. 4-6, it can be said that the side plate 3 has a three-step structure, with the front surface 31 of the first step located on the upper surface of the side plate 3, the side surface 32 of the first step located on the upper inner surface of the side plate 3, the front surface 41 of the second step located in the same plane with the upper surface of the protrusion 4 (the upper surface of the protrusion 4 can he deemed as a part of the front surface 41 of the second step), the side surface 42 of the second step extending from the front surface 41 of the second step perpendicularly to the lower surface of the protrusion or the bottom surface, and the bottom surface equivalent to the front surface of the third step. On this condition, the display panel may be adhered to the side surface 32 of the first step and the front surface 41 of the second step.

By the method for producing a display module of this embodiment, the backboard, the plastic central frame and the front frame of the display module such as conventional television can be replaced with a rear cover. Each layer of the display module can be assembled via the rear cover, without the need for the front frame and the central frame. This dramatically reduces the components or the key materials for the display module, which helps to lighten the weight of the display module, shorten the supply chain and save the cost for the materials. Several key materials are integrated in the rear cover, thereby further lowering the cost. The rear cover with a simplified design can help to save the working hours and labors and eliminate incompatibility between the materials, so that the precision of assembly and the yield of production can be greatly improved.

### Embodiment 2

FIGS. 3a and 3b are diagrams respectively showing enlarged structures of a part of a display module according to an embodiment of the present disclosure. Referring to FIGS. 3a and 3b, the display module mainly comprises: a rear cover 1 including an accommodating cavity 11 formed by a bottom plate 2 and a side plate 3, a reflective sheet 71 located on an upper surface of the rear cover 1, a backlight source 6 located above the reflective sheet 71 and connected to the side plate 3, a light guide plate 7 located above the reflective sheet 71 and the backlight source 6 and connected to the side plate 3, an optical film 13 located above the light guide plate 7 and connected to the side plate 3, a display panel 12 located above the optical film 13 and fixed to the side plate 3, wherein, the reflective sheet 71, the backlight source 6, the light guide plate 7 and the optical film 13 are located within the accommodating cavity 11.

In one possible implementation, referring to FIGS. 3a to 5, a protrusion 4 protruding toward the inside of the accommodating cavity 11 is provided on an inner surface of the side plate 3, a groove 5 is formed between the protrusion 4 and the bottom plate 2, and the backlight source 6 and the light guide plate 7 are provided within the groove 5.

In one possible implementation, referring to FIG. 8, a recess 8 for housing electrical connection terminals of the backlight source 6 is provided on a part of the bottom plate 2 that is adjacent to the groove 5. Referring to FIG. 8, a recess 8 for accommodating the electrical connection terminals 9 of the backlight source 6 can be provided on the bottom plate 2 of the groove 5 adjacent to the light entering side. There may be one or more recesses. All of the terminals may be placed in one recess 8. Also, a recess may be respectively provided for each of a plurality of terminals. The electrical connection terminals 9 can be connected to an external power (not show) so as to supply power for the backlight source 6. In addition, the power wire (not shown) of the backlight source 6 might be extremely thin, for instance, in this embodiment, is about 0.1 mm. The power wire may be attached to the inner surface of the rear cover 1, so that the wiring of the backlight module or display module has a better appearance and is safer.

In one possible implementation, referring to FIG. 6, a plurality of film hangers 10 are provided on the protrusion 4, and the optical film 13 is hitched to the film hangers 10 with a lower surface of the optical film 13 in contact with an upper surface of the light guide plate 7. Specific configuration of the film hanger 10 may refer to FIG. 6 and the relevant description in the afore-mentioned embodiment.

In one possible implementation, referring to FIGS. 3a to 5, the display panel 12 is adhered to an inner surface of the side plate 3 and an upper surface of the protrusion 4. The specific description may refer to the relevant description in the afore-mentioned embodiment and FIGS. 3a and 3b.

In the display module of this embodiment, the backboard, the plastic central frame and the front frame of the display module such as conventional television can be replaced with a rear cover. Each layer of the display module can be assembled via the rear cover, without the need for the front frame and the central frame. This dramatically reduces the components or the key materials for the display module, which helps to lighten the weight of the display module, shorten the supply chain and save the cost for the materials. Several key materials are integrated in the rear cover, thereby further lowering the cost. The rear cover with a simplified design can help to save the working hours and labors and eliminate incompatibility between the materials, so that the precision of assembly and the yield of production can be greatly improved. Moreover, by providing a recess in the bottom plate, the structure of the display module is more compact, which facilitates the assembly and obtains a lighter and thinner display module.

Afore-mentioned are merely specific embodiments of the present disclosure, but the protection scope of the present disclosure is not limited to these embodiments. Within the technical scope disclosed in the present disclosure, changes or replacement that may easily occur to any one skilled in the art should be included within the protection scope of the present disclosure. Therefore, the protection scope of the present disclosure should be subject to the protection scopes of the claims.

1. A method for producing a display module, comprising:
providing a reflective sheet inside an accommodating cavity of a rear cover of the display module, the accommodating cavity being formed by a bottom plate and a side plate of the rear cover;
providing a backlight source above the reflective sheet, and fixing the backlight source to an inner surface of the side plate;
providing a light guide plate above the reflective sheet and on a side of the backlight source, and connecting the light guide plate to the side plate;
providing an optical film above the light guide plate, and connecting the optical film to the side plate; and
providing a display panel above the optical film, and fixing the display panel to the side plate.

2. The method according to claim 1, wherein providing the backlight source above the reflective sheet comprises:
providing the backlight source in a groove between the side plate and the bottom plate, wherein a protrusion protruding toward the inside of the accommodating cavity is provided on an inner surface of the side plate, and the groove is formed between the protrusion and the bottom plate.

3. The method according to claim 2, wherein the protrusion is provided on inner surfaces of two side plates, facing each other, of the rear cover.

4. The method according to claim 2, wherein connecting the light guide plate to the side plate comprises:
engaging at least one side of the light guide plate with the groove.

5. The method according to claim 4, wherein connecting the optical film to the side plate comprises:
hitching the optical film to a film hanger located on the protrusion in such manner that a lower surface of the optical film is in contact with an upper surface of the light guide plate.

6. The method according to claim 5, wherein fixing the display panel to the side plate comprises:
adhering the display panel to the inner surface of the side plate and an upper surface of the protrusion.

7. A display module, comprising:
a rear cover comprising an accommodating cavity, the accommodating cavity being formed by a bottom plate and a side plate of the rear cover;
a reflective sheet located on an upper surface of the bottom plate;
a backlight source located above the reflective sheet and connected to the side plate;
a light guide plate located above the reflective sheet and on a side of the backlight source and connected to the side plate;
an optical film located above the light guide plate and connected to the side plate; and
a display panel located above the optical film and fixed to the side plate,
wherein, the reflective sheet, the backlight source, the light guide plate and the optical film are located within the accommodating cavity.

8. The display module according to claim 7, wherein a protrusion protruding toward the inside of the accommodating cavity is provided on an inner surface of the side plate, a groove is formed between the protrusion and the bottom plate, and the backlight source and the light guide plate are provided within the groove.

9. The display module according to claim 8, wherein the protrusion is provided on inner surfaces of two side plates, facing each other, of the rear cover.

10. The display module according to claim 8, wherein a recess for housing an electrical connection terminal of the backlight source is provided on a part of the bottom plate that is adjacent to the groove.

11. The display module according to claim 9, wherein a plurality of film hangers are provided on the protrusion, and the optical film is hitched to the film hangers with a lower surface of the optical film in contact with an upper surface of the light guide plate.

12. The display module according to claim 10, wherein the display panel is adhered to the inner surface of the side plate and an upper surface of the protrusion.

13. The method according to claim 2, wherein the groove is configured to press the light guide plate.

14. The display module according to claim 8, wherein the groove is configured to press the light guide plate.
